(19) United States
(12) Patent Application Publication
(10) Pub. No.: US 2023/0326722 A1
(43) Pub. Date: Oct. 12, 2023

(54) GAS-DELIVERY ASSEMBLY AND REACTOR SYSTEM INCLUDING SAME

(71) Applicant: ASM IP Holding B.V., Almere (NL)

(72) Inventors: Thomas Fitzgerald, Gilbert, AZ (US); Ruchik Bhatt, Chandler, AZ (US)

(21) Appl. No.: 18/129,932

(22) Filed: Apr. 3, 2023

Related U.S. Application Data
(60) Provisional application No. 63/327,910, filed on Apr. 6, 2022.

(51) Int. Cl. H01J 37/32

(52) U.S. Cl. CPC H01J 37/3244; H01J 37/32633; H01J 37/32357; H01J 2237/002; H01J 2237/338

(57) ABSTRACT

A gas-delivery assembly and reactor system including the gas-delivery system are disclosed. The gas-delivery assembly includes a transport tube and a baffle to facilitate desired distribution of gas that can include activated species.

### CROSS-REFERENCE TO RELATED APPLICATIONS

This application is a nonprovisional of, and claims priority to and the benefit of, U.S. Provisional Patent Application No. 63/327,910, filed Apr. 6, 2022 and entitled “GAS-DELIVERY ASSEMBLY AND REACTOR SYSTEM INCLUDING SAME,” which is hereby incorporated by reference herein.

### FIELD OF INVENTION

The present disclosure generally relates to assemblies for providing gas to a reaction chamber and to gas-phase reactor systems. More particularly, the disclosure relates to gas-delivery assemblies suitable for providing activated species to a reaction chamber and to reactor systems including a gas-delivery assembly.

### BACKGROUND OF THE DISCLOSURE

Reactor systems are often used during the fabrication of electronic devices, such as semiconductor devices. For several fabrication processes, it may be desirable to form activated species, such as radicals, to, for example, allow for desired reactions to occur at relatively low temperatures, compared to temperatures for the desired reactions without the aid of activated species.

For example, hydrogen radicals can be used to treat a surface of a substrate within a reaction chamber at relatively low temperatures. Such treatment can include cleaning, providing desired surface termination, and/or removing a native oxide from the substrate surface.

Generally, during surface treatment with activated species, it is desirable to have a uniform distribution of activated species provided to the surface of the substrate within the reaction chamber to provide uniform treatment across the substrate surface. One approach to providing uniform distribution of activated species includes use of a showerhead device. However, activated species, such as hydrogen radicals, have a low diffusion rate due to their low mass, and hydrogen radicals tend to recombine after colliding with a surface, such as a surface within the showerhead device. As a result, with typical showerhead devices, hydrogen radicals can readily recombine, resulting in non-uniform distribution of the radicals to the substrate surface.

Accordingly, improved assemblies and systems for providing a more uniform distribution of activated species are desired.

### SUMMARY OF THE DISCLOSURE

Various embodiments of the present disclosure provide improved assemblies and systems for providing activated species (e.g., hydrogen radicals) to a surface of a substrate. Exemplary methods and systems can be used to remove carbon-containing material and/or oxygen-containing material from a surface of a substrate and/or reduce a metal oxide, such as cobalt oxide or the like. While the ways in which the various drawbacks of the prior art are discussed in greater detail below, in general, the assemblies and systems described herein can provide a relatively high concentration and/or uniform distribution of activated species across a surface of a substrate.

In accordance with at least one exemplary embodiment of the disclosure, a gas-delivery assembly includes a transport tube, a showerhead assembly, and a baffle. In accordance with aspects of these embodiments, the transport tube includes a first end having a first end cross-sectional dimension and a second end having a second end cross-sectional dimension, wherein the first end cross-sectional dimension is smaller than the second end cross-sectional dimension. In accordance with further aspects, the showerhead assembly is coupled to the second end of the transport tube. The showerhead assembly includes a top plate; a showerhead plate coupled to the top plate; and a plenum region between the top plate and the showerhead plate. In accordance with further aspects, the baffle is interposed between the plenum region and the second end. An exemplary baffle includes a first region and a second region radially exterior the first region, wherein a fluid conductance of the second region is greater than a fluid conductance of the first region. The gas-delivery assembly can further include a first flange coupled to the second end and to the top plate. The first flange can include a first flange cooling fluid channel. The gas-delivery assembly can further include a second flange coupled to the first end. The second flange can include a second flange cooling fluid channel. One or more of the transport tube and the baffle can include a coating. The coating can be configured to mitigate recombination of radicals.

In accordance with additional embodiments of the disclosure, a reactor system includes a remote plasma unit, a reaction chamber, and a gas-delivery assembly. The gas-delivery assembly can be as described herein.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 illustrates a reactor system in accordance with at least one embodiment of the disclosure.

FIG. 2 illustrates an enlarged view of a portion of the reactor system of FIG. 1.

FIG. 3 illustrates an enlarged view of a portion of the reactor system of FIG. 1.

FIG. 4 illustrates a portion of a gas-delivery assembly in accordance with at least one embodiment of the disclosure.

FIGS. 5 and 6 illustrate cross-sectional views of the portion of the gas-delivery assembly of FIG. 4 in accordance with at least one embodiment of the disclosure.

FIG. 7 illustrates a baffle in accordance with at least one embodiment of the disclosure.

It will be appreciated that elements in the figures are illustrated for simplicity and clarity and have not necessarily been drawn to scale. For example, the dimensions of some of the elements in the figures may be exaggerated relative to other elements to help to improve understanding of illustrated embodiments of the present disclosure.

### DETAILED DESCRIPTION OF EXEMPLARY EMBODIMENTS

The description of exemplary embodiments of assemblies and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features.

As set forth in more detail below, exemplary assemblies and systems described herein can be used in the manufacture of electronic devices, such as semiconductor devices. In particular, exemplary systems can be used to provide a relatively high and/or uniform concentration of activated species (e.g., derived from hydrogen) to a surface of a substrate for use in a variety of applications—particularly when relatively low process temperatures are desirable.

Reduced processing temperature may be desired to minimize or reduce degradation or damage of other layers on or with a substrate. Activated species, such as hydrogen radicals generated by remote plasma sources, can enable reduction of materials at relatively low temperatures, such as below 200° C., 250° C. 300° C., or 350° C. The low temperature treatment facilitates maintaining the integrity and continuity of material on a substrate and can reduce damage that might otherwise occur—e.g., to other layers within the substrate. Hydrogen radicals can be used to reduce metal oxide to metal. The hydrogen radicals can also be used to clean contaminates, such as carbon, from a surface of a substrate. Additionally or alternatively, hydrogen radicals can be used to provide desired surface termination—e.g., for subsequent processing. In addition, hydrogen radicals have relatively low kinetic energy, thereby mitigating substrate damage during a process. Various embodiments of the disclosure provide assemblies and systems to transport activated species, such as hydrogen radicals, to a substrate—e.g., for a surface treatment.

As used herein, the term substrate can refer to any underlying material or materials upon which a layer can be deposited. A substrate can include a bulk material, such as silicon (e.g., single-crystal silicon) or other semiconductor material, and can include one or more layers, such as native oxides or other layers, overlying or underlying the bulk material. Further, the substrate can include various topologies, such as recesses, lines, and the like formed within or on at least a portion of a layer and/or bulk material of the substrate. By way of particular examples, a substrate may comprise one or more materials including, but not limited to, silicon (Si), germanium (Ge), germanium tin (GeSn), silicon germanium (SiGe), silicon germanium tin (SiGeSn), silicon carbide (SiC), or a group III-V semiconductor material, such as, for example, gallium arsenide (GaAs), gallium phosphide (GaP), or gallium nitride (GaN). In some embodiments, the substrate may comprise one or more dielectric materials including, but not limited to, oxides, nitrides, or oxynitrides. For example, the substrate may comprise a silicon oxide (e.g., SiO₂), a metal oxide (e.g., Al₂O₃), a silicon nitride (e.g., Si₃N₄), or a silicon oxynitride. In some embodiments of the disclosure, the substrate may comprise an engineered substrate wherein a surface semiconductor layer is disposed over a bulk material with an intervening buried oxide (BOX) disposed therebetween. Patterned substrates can include features formed into or onto a surface of the substrate; for example, a patterned substrate may comprise partially fabricated semiconductor device structures, such as, for example, transistors and/or memory elements. In some cases, the substrate includes a layer comprising a metal, such as copper, cobalt, and the like.

As used herein, the term film can refer to any continuous or non-continuous structures and material, such as material deposited by the methods disclosed herein. For example, a film can include 2D materials or partial or full molecular layers or partial or full atomic layers or clusters of atoms and/or molecules. A film can include material with pinholes, but still be at least partially continuous. The terms film and layer can be used interchangeably.

In this disclosure, gas may include material that is a gas at normal temperature and pressure, a vaporized solid and/or a vaporized liquid, and may be constituted by a single gas or a mixture of gases, depending on the context.

Further, in this disclosure, any two numbers of a variable can constitute a workable range of the variable, and any ranges indicated may include or exclude the endpoints. Additionally, any values of variables indicated (regardless of whether they are indicated with about or not) may refer to precise values or approximate values and include equivalents, and may refer to average, median, representative, majority, or the like. in some embodiments. Further, in this disclosure, the terms including, constituted by and having can refer independently to typically or broadly comprising, comprising, consisting essentially of, or consisting of in some embodiments. In accordance with aspects of the disclosure, any defined meanings of terms do not necessarily exclude ordinary and customary meanings of the terms.

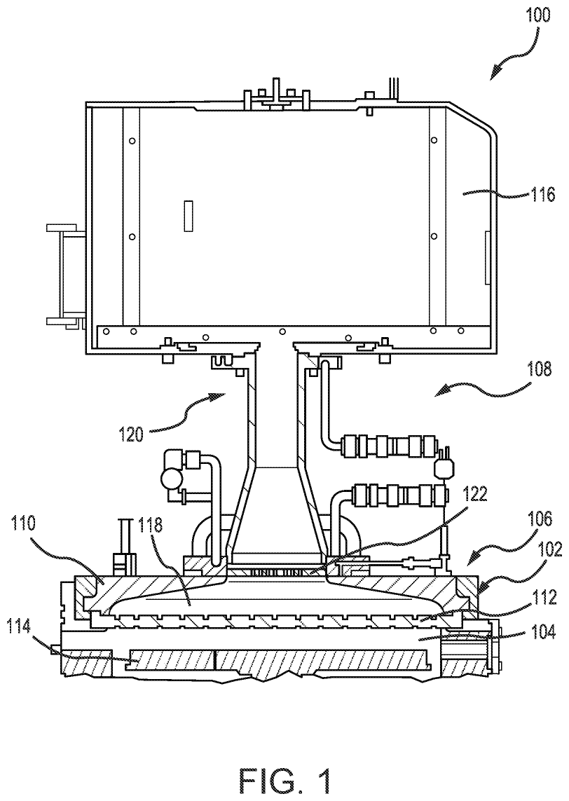

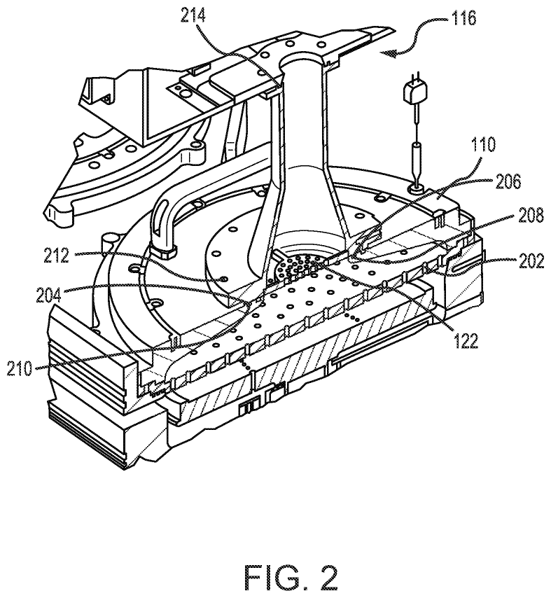

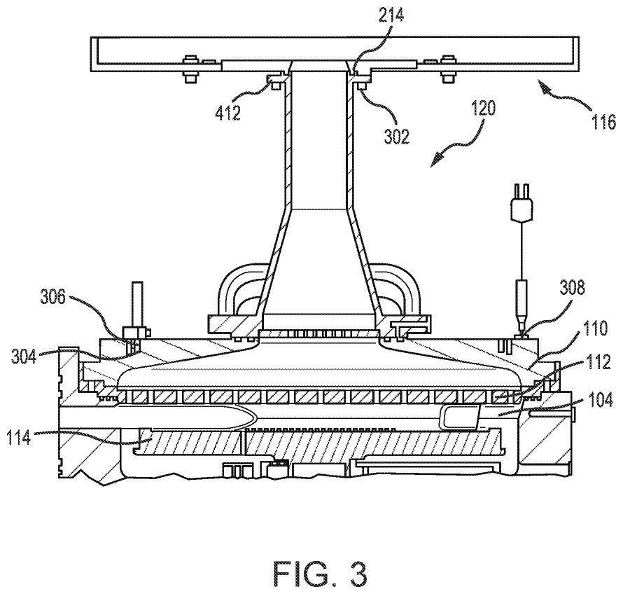

Turning now to the figures, FIG. 1 illustrates a reactor system 100 in accordance with exemplary embodiments of the disclosure. FIGS. 2 and 3 illustrate enlarged views of a portion of the reactor system 100. The reactor system 100 includes a reactor 102, including a reaction chamber 104; a gas-delivery assembly 108; and a remote plasma unit (RPU) 116. The reactor system 100, as well as gas-delivery assemblies described herein, can provide extended lifetimes to activated species (e.g., hydrogen radicals) within the reactor system and/or components thereof and/or can provide more uniform distribution and/or desired distribution of the activated species.

The reactor 102 can be or include any suitable gas-phase reactor. By way of examples, the reactor 102 can be or include a treatment reactor. As illustrated, the reactor 102 can include a substrate support 114 to support a substrate during processing.

The reaction chamber 104, at least in part, defines a space in which a substrate is processed. A lower portion or surface of the reaction chamber 104 can be defined, at least in part, by the substrate support 114.

The gas-delivery assembly 108 includes a showerhead assembly 106, a transport tube 120, and a baffle 122. The gas-delivery assembly 108 is configured to provide activated species from the remote plasma unit 116 to the reaction chamber 104, while mitigating recombination of radicals formed within the remote plasma unit. Further, the gas-delivery assembly 108 can provide the activated species while mitigating any pressure drop between remote the plasma unit 116 and the reaction chamber 104.

The showerhead assembly 106 includes a top plate 110, a showerhead plate 112 coupled to the top plate 110, and a plenum region 118 between the top plate 110 and the showerhead plate 112. The top plate 110 can be formed of any suitable material, such as metal. By way of example, the top plate 110 can be formed of aluminum—e.g., various aluminum grades (e.g., 6000 Series or 5000 Series) or an aluminum alloy, any of which can include different surface coatings. Similarly, the showerhead plate 112 can be formed of any suitable metal, such as various aluminum grades (e.g., 6000 Series or 5000 Series) or an aluminum alloy, with different surface coatings. The top plate 110 can also include a top plate conduit 304 and a heater 306 therein. The heater 306 can be, for example, a flexible, resistive heater. A thermocouple 308 can also be at least partially embedded in top plate 110.

The showerhead plate 112 includes a plurality of holes 202 to facilitate desired flow of gas from the plenum region 118 to the reaction chamber 104.

The transport tube 120 is configured to transport activated species formed in the remote plasma unit 116 to the plenum region 118 of the showerhead assembly 106, while mitigating recombination of radicals. The transport tube 120 can be formed of any suitable material, such as aluminum—e.g., 6000 or 50000 Series aluminum grades or an aluminum alloy—with different surface coatings. An interior surface 524 of the transport tube 120 can be coated with tube coating, such as aluminum oxide, electroless nickel phosphorus, yttrium oxide, or the like to further mitigate recombination of radicals.

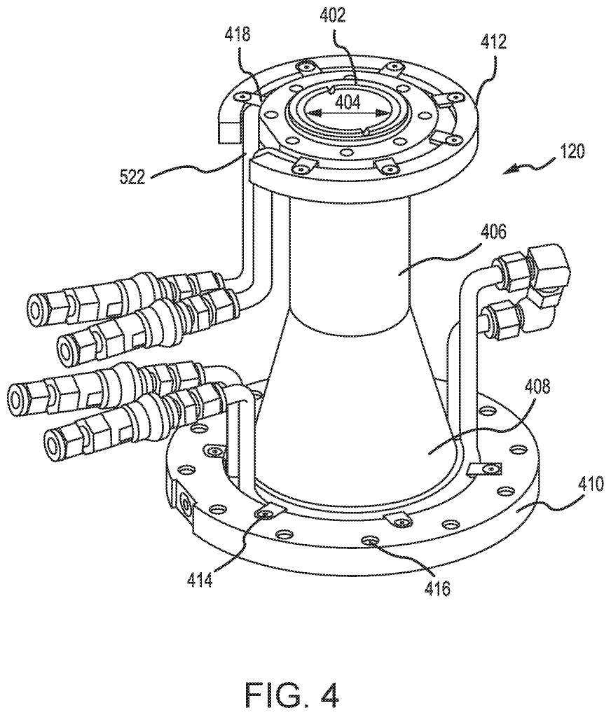

Referring to FIGS. 1 and 4-6, in the illustrated example, the transport tube 120 includes a first end 402 having a first end cross-sectional dimension (e.g., a first diameter) 404, and a second end 502 having a second end cross-sectional dimension (e.g., a second diameter) 504, wherein the first end cross-sectional dimension 404 is smaller than the second end cross-sectional dimension 504. The second end cross-sectional dimension 504, being larger than the first end cross-sectional dimension 404, facilitates flow of the activated species to the reaction chamber 104, while mitigating recombination. The second end 502 can coupled to the showerhead assembly 106.

As further illustrated, the transport tube 120 includes a first section 406 and an adjacent second section 408. The first section 406 can be a substantially straight, hollow, cylindrical shape. The second section 408 can be a tapered or substantially frustoconical shaped. The first section 406 and the second section 408 can be formed as a unitary body. Alternatively, the first section 406 and the second section 408 can be sealably coupled together.

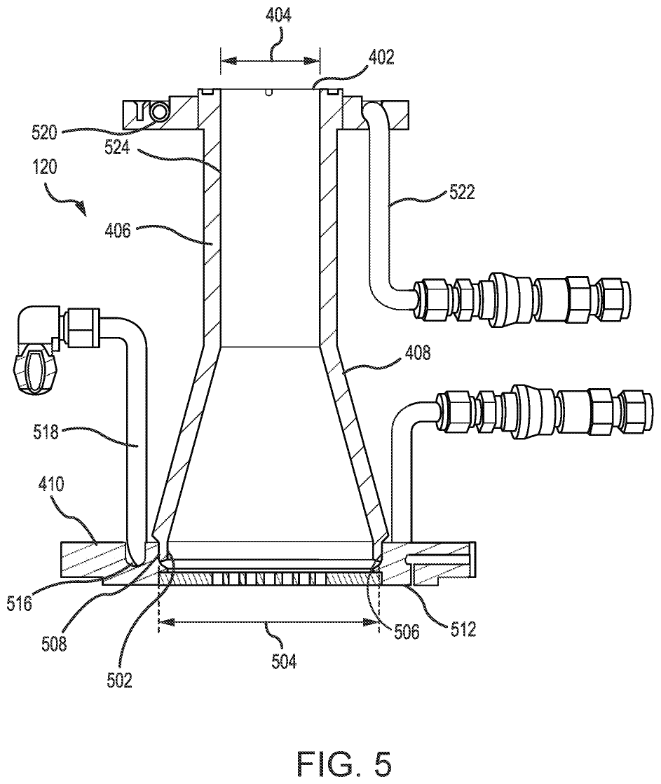

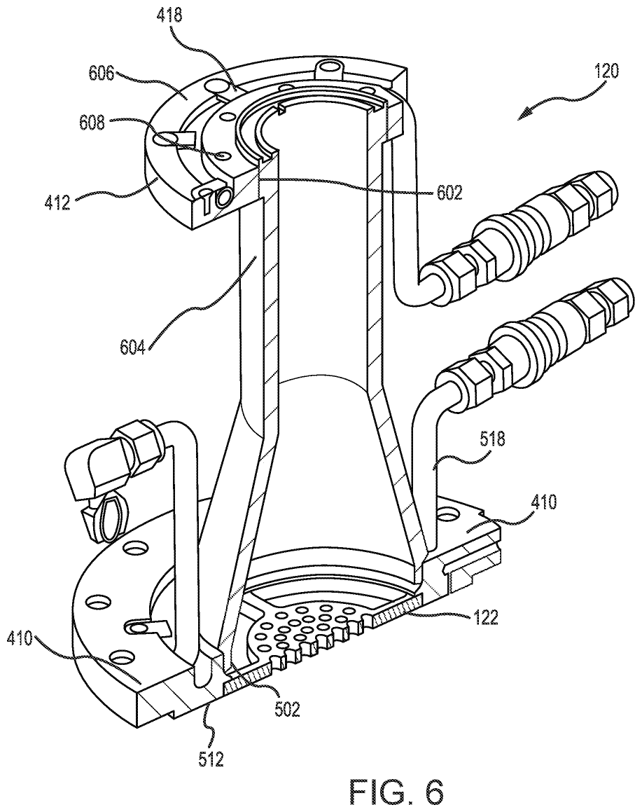

The gas-delivery assembly 108 can also include a first flange 410. The first flange 410 can be used to couple the second end 502 of the transport tube 120 to the top plate 110. As illustrated in FIGS. 5 and 6, the first flange 410 includes an inner surface 506, which contacts the outer surface 508 of the transport tube 120 to form a seal between the transport tube 120 and the first flange 410. In some cases, the first flange 410 (e.g., inner surface 506) is welded to the second end 502 (e.g., the outer surface 508).

The first flange 410 also includes a bottom surface 512 that forms a seal between the top plate 110 and the first flange 410. The seal can be formed using any suitable means. For example, as illustrated in FIG. 2, the top plate 110 can include recesses 208, 210 and sealing members 204, 206 (e.g., O-rings or the like) to form a seal between the top plate 110 and the first flange 410.

The first flange 410 can also include a first flange cooling fluid channel 516. The first flange cooling fluid channel 516 can be configured to receive a cooling fluid tube 518 that has a cooling fluid circulated therethrough and/or the cooling fluid channel 516 can be configured to receive a cooling fluid directly. The gas-delivery assembly 108 can also include one or more fasteners, such as one or more clips 414 to retain the cooling fluid tube 518 within the first flange cooling fluid channel 516.

The first flange 410 can also include a plurality of holes 416 to receive fasteners 212, such as bolts or screws. The fasteners 212 can be used to couple the first flange 410 to the top plate 110.

The gas-delivery assembly 108 can also include a second flange 412. The second flange 412 can be used to couple the first end 402 of the transport tube 120 to the remote plasma unit 116.

The second flange 412 includes an inner surface 602, which contacts the outer surface 604 of the transport tube 120 to form a seal between the transport tube 120 and the second flange 412. In some cases, the second flange 412 (e.g., inner surface 602) can be welded to the first end 402 (e.g., outer surface 604).

The second flange 412 also includes a top surface 606 that can form a seal between the remote plasma unit 116 and the second flange 412. The seal can be formed using any suitable means. For example, as illustrated in FIGS. 2 and 3, a sealing member 214 (e.g., O-rings or the like) can be used to form a seal between the second flange 412 and the remote plasma unit 116.

The second flange 412 can include a second flange cooling fluid channel 520. The second flange cooling fluid channel 520 can be configured to receive a cooling fluid tube 522 that can have a cooling fluid circulated therethrough and/or can be configured to receive a cooling fluid directly. The gas-delivery assembly 108 can also include one or more fasteners, such as one or more clips 418 to retain the cooling fluid tube 522 within the second flange cooling fluid channel 520.

The second flange 412 can also include a plurality of holes 608 to receive fasteners 302, such as bolts or screws. The fasteners 302 can be used to couple the second flange 412 to the remote plasma unit 116, such that the first end 402 of the transport tube 120 is fluidly coupled to an outlet of the remote plasma unit 116.

The baffle 122 can be configured to distribute activate species generated in the remote plasma unit 116 to the plenum region 118. The baffle 122 can therefore suitably be interposed between the plenum region 118 and the second end 502. The baffle 122 can be sealably coupled to the first flange 410. For example, the baffle 122 can be welded to the first flange 410.

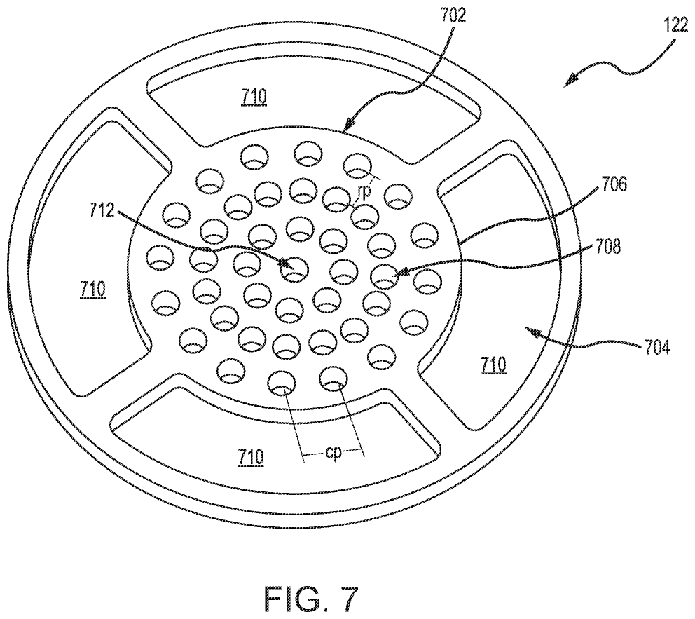

FIG. 7 illustrates an exemplary baffle 122 in greater detail. In the illustrated example, the baffle 122 includes a first region 702 and a second region 704, which is disposed radially exterior of the first region 702. To obtain a desired flow pattern of activated species, a fluid conductance of the second region 704 can be greater than a fluid conductance of the first region 702.

The first region 702 can include a substantially cylindrical portion 706 having a plurality of holes 708 therethrough. The first region 702 can be configured to allow activated species to flow toward a center of a substrate within the reaction chamber 104, while not allowing all of the activated species to flow directly toward the center of the substrate. A number of holes 708 can range from, for example, about 10 to about 50 or about 20 to about 100. A size of each hole 708 can range from about 1 to about 7 mm. A circumferential pitch (cp) of neighboring holes 708 can vary radially, with, for example, holes 708 closer together near a center 712 of the baffle 122 relative to the spacing of the holes 708 away from the center 712. In some cases, a radial pitch (rp) of the holes 708 can be relatively constant.

The second region 704 can include a substantially hollow, cylinder shape. In the illustrated example, the second region 704 includes a plurality of arcuate-shaped or substantially arcuate-shaped regions 710. A number of arcuate-shaped regions can range from, for example, about 2 to about 4 or about 4 to about 8.

The baffle 122 can be formed of any suitable material, such as a metal or ceramic (e.g., sapphire, quartz, fused silica, or the like). Exemplary metals include aluminum of various grades, such as those noted herein, aluminum alloys, refractory metals, and the like. In some cases, the baffle 122 comprises a baffle coating on a surface of the baffle. The baffle coating can be or include, for example, aluminum oxide, electroless nickel phosphorous, yttrium oxide, or the like.

Referring again to FIG. 1, the susceptor or substrate support 114 can be stationary and can be configured to receive lift pins (not illustrated). The susceptor 114 can include one or more heaters and/or one or more conduits for cooling fluid.

The remote plasma unit 116 generates activated species (e.g., radicals) from one or more source gases (e.g., hydrogen-containing gas, such as H₂). The generated radicals then enter the reaction chamber 104 through the transport tube 120. The remote plasma unit 116 may include: a toroidal style ICP (inductively coupled plasma) and/or CCP (capacitively coupled plasma) source or a coil style ICP source driven by different RF frequencies, such as a 100 kHz, 400 kHz, 2 MHz, 13.56 MHz, 60 MHz, 160 MHz and/or 2.45 GHz microwave source.

Although exemplary embodiments of the present disclosure are set forth herein, it should be appreciated that the disclosure is not so limited. For example, although the systems and assemblies are described in connection with hydrogen radicals, the systems and assemblies are not necessarily limited to use with such radicals. Various modifications, variations, and enhancements of the system and method set forth herein may be made without departing from the spirit and scope of the present disclosure.

We claim:

1. A gas-delivery assembly comprising:
a transport tube comprising:
a first end having a first end cross-sectional dimension, and
a second end having a second end cross-sectional dimension,
wherein the first end cross-sectional dimension is smaller than the second end cross-sectional dimension;
a showerhead assembly coupled to the second end, the showerhead assembly comprising:
a top plate;
a showerhead plate coupled to the top plate; and
a plenum region between the top plate and the showerhead plate; and
a baffle interposed between the plenum region and the second end, the baffle comprising:
a first region; and
a second region radially exterior the first region,
wherein a fluid conductance of the second region is greater than a fluid conductance of the first region.

2. The gas-delivery assembly of claim 1, further comprising a first flange coupled to the second end and to the top plate.

3. The gas-delivery assembly of claim 2, wherein the first flange is welded to the second end.

4. The gas-delivery assembly of claim 2, wherein the baffle is welded to the first flange.

5. The gas-delivery assembly of claim 2, wherein the first flange comprises a first flange cooling fluid channel.

6. The gas-delivery assembly of claim 1, further comprising a second flange coupled to the first end.

7. The gas-delivery assembly of claim 6, wherein the second flange comprises a second flange cooling fluid channel.

8. The gas-delivery assembly of claim 1, wherein the first region comprises a substantially cylindrical portion having a plurality of holes therethrough.

9. The gas-delivery assembly of claim 1, wherein the second region comprises a plurality of arcuate-shaped regions.

10. The gas-delivery assembly of claim 1, wherein the top plate comprises a top plate conduit and a heater therein.

11. The gas-delivery assembly of claim 1, wherein the transport tube further comprises a tube coating on an interior surface of the transport tube.

12. The gas-delivery assembly of claim 11, wherein the tube coating comprises a material selected from the group consisting of aluminum oxide, electroless nickel phosphorous, and yttrium oxide.

13. The gas-delivery assembly of claim 1, wherein the baffle further comprises a baffle coating on a surface of the baffle.

14. The gas-delivery assembly of claim 13, wherein the baffle coating comprises a material selected from the group consisting of aluminum oxide, electroless nickel phosphorous, and yttrium oxide.

15. The gas-delivery assembly of claim 1, wherein the transport tube comprises a first substantially straight section and an adjacent second tapered section.

16. A reactor system comprising:
a remote plasma unit;
a transport tube fluidly coupled to an outlet of the remote plasma unit, the transport tube comprising:
a first end having a first end cross-sectional dimension, and
a second end having a second end cross-sectional dimension,
wherein the first end cross-sectional dimension is smaller than the second end cross-sectional dimension;
a showerhead assembly coupled to the second end, the showerhead assembly comprising:
a top plate;
a showerhead plate coupled to the top plate; and
a plenum region between the top plate and the showerhead plate;
a baffle interposed between the plenum region and the second end, the baffle comprising:
a first region; and
a second region radially exterior the first region,
wherein a fluid conductance of the second region is greater than a fluid conductance of the first region; and
a reaction chamber adjacent the showerhead plate.

17. The reactor system of claim 16, wherein the transport tube is coated with a material selected from the group consisting of aluminum oxide, electroless nickel phosphorous p, and yttrium oxide.

18. A gas-delivery assembly comprising:
a transport tube comprising:
a first end having a first end cross-sectional dimension,
a second end having a second end cross-sectional dimension,
wherein the first end cross-sectional dimension is smaller than the second end cross-sectional dimension,
a showerhead assembly coupled to the second end, the showerhead assembly comprising:
a top plate;
a showerhead plate coupled to the top plate; and
a plenum region between the top plate and the showerhead plate; and
a baffle interposed between the plenum region and the second end.

19. The gas-delivery assembly of claim 18 comprising a first flange comprising a first flange cooling fluid channel.

20. The gas-delivery assembly of claim 18, comprising a second flange comprising a second flange cooling fluid channel.
